(19) United States
(12) Patent Application Publication
(10) Pub. No.: US 2026/0096426 A1
(43) Pub. Date: Apr. 2, 2026

(54) HEAT DISSIPATION STRUCTURE FOR INTEGRATED CIRCUIT PACKAGES

(71) Applicant: Taiwan Semiconductor Manufacturing Company, Ltd., Hsinchu (TW)

(72) Inventors: Hsin-Yu Chen, Taipei City (TW); Yu-Hsiang Hu, Hsinchu City (TW); Meng-Wei Chou, Hsinchu County (TW); Chien-Hsun Lee, Hsin-Chu County (TW); Kathy Wei Yan, Hsinchu (TW)

(21) Appl. No.: 19/008,225

(22) Filed: Jan. 2, 2025

Related U.S. Application Data
(60) Provisional application No. 63/699,949, filed on Sep. 27, 2024.

(51) Int. Cl. H01L 23/373; H01L 23/04; H01L 23/06; H01L 23/29; H01L 23/498

(52) U.S. Cl. CPC H10W 40/258; H10W 70/666; H10W 74/40; H10W 76/12; H10W 76/17; H10W 90/701

(57) ABSTRACT

A package structure according to the present disclosure includes a package substrate, an interposer bonded to the package substrate, a first die and a second die bonded to the interposer by way of micro bumps, an underfill surrounding the micro bumps, disposed between the first die and the interposer as well as between the second die and the interposer, a metal layer interfacing the interposer, the underfill, sidewalls of the first die, and sidewalls of the second die, a molding material over the metal layer, and a thermal interface material disposed over the molding material, the metal layer, the first die, and the second die.

### PRIORITY DATA

This application claims the benefit of U.S. Provisional Application No. 63/699,949, filed Sep. 27, 2024, which is hereby incorporated by reference in its entirety.

### BACKGROUND

In some Three-Dimensional Integrated Circuits (3DIC), device dies are bonded to a package substrate to form a package. The heat generated by the device dies during operation needs to be dissipated to prevent performance degradation or even physical damage. Additionally, the package structure may lack structural strength to prevent warping.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method 100 for forming a package structure, according to various aspects of the present disclosure.

FIGS. 2-24 illustrates fragmentary cross-sectional views or top views of a work-in-progress structure going through various steps of the method 100 in FIG. 1, according to various aspects of the present disclosure.

FIGS. 25-32 illustrate alternative package structures formed using a modified method 100, according to various aspects of the present disclosure.

### DETAILED DESCRIPTION

The following disclosure provides many different embodiments, or examples, for implementing unique features of the provided subject matter. Specific examples of components and arrangements are described below to simplify the present disclosure.

These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the countless examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Semiconductor packaging technologies were once just considered backend processes that facilitates chips to interface external circuitry. It is no longer the case. Computing workloads have evolved so much that brought packaging technologies to the forefront of innovation. Modern packaging provides integration of multiple chips or dies into a single semiconductor device. Depending on the level of stacking, modern semiconductor packages can have a 2.5D structure or a 3D structure. In a 2.5D structure, at least two dies are coupled to a redistribution layer (RDL) structure or an interposer that provides chip-to-chip communication. The at least two dies in a 2.5D structure are not stacked one over another vertically. In a 3D structure, at least two dies are stacked one over another and interact with each other by way of through silicon vias (TSVs). Depending on the processes adopted, the 2.5D structure and the 3D structure may have an Integrated Fan-Out (InFO) construction or a Chip-on-Wafer-on-Substrate (CoWoS®) construction. For high-power-density 3DIC packages, such as System-on-Chip (SoC) or System-on-Integrated-Chips (SoIC) packages, heat cannot be effectively distributed or dissipated through a silicon substrate and hot spots may be formed in the dies, which may cause overheating and burnt-out failure. Insulating molding compounds and under fill materials around the dies are poor thermal conductors and do not help much with heat dissipation.

The present disclosure provides a method of forming a package structure where a metal layer is deposited over an under fill below and around the dies. The metal layer extends along sidewalls of the dies and upward to interface a thermal interface material (TIM). The metal layer helps conduct heat toward the TIM and further heat sink structures. In some embodiments, the dies are bonded to an interposer and a portion of the metal layer interfaces a top surface of the interposer. In some further embodiments, the interposer includes a seal ring structure around the edges of the interposer and the metal layer interfaces the seal ring structure. It allows the heat to be directed downward into the package substrate.

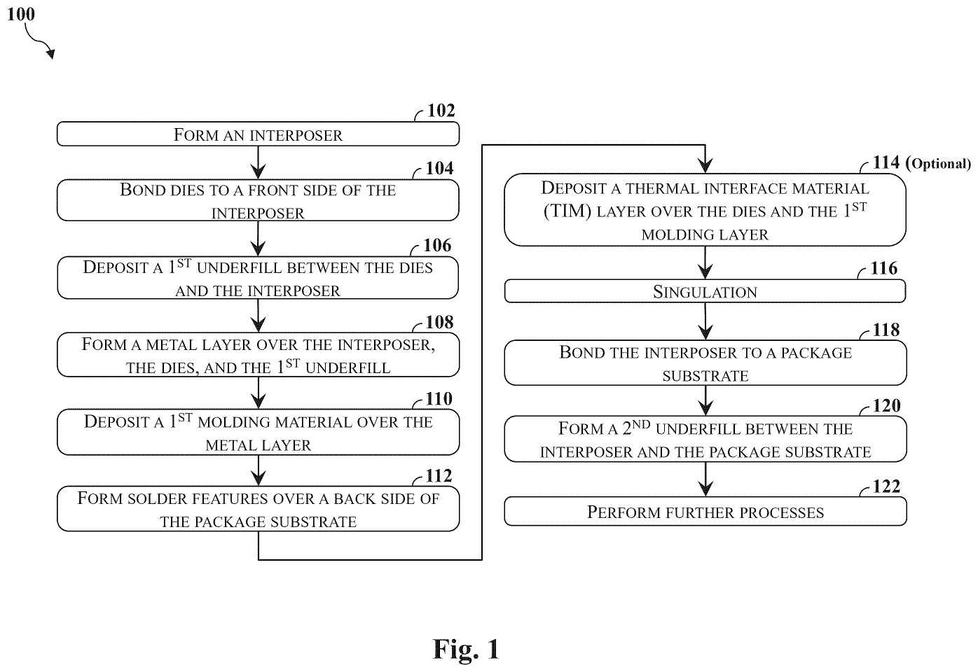

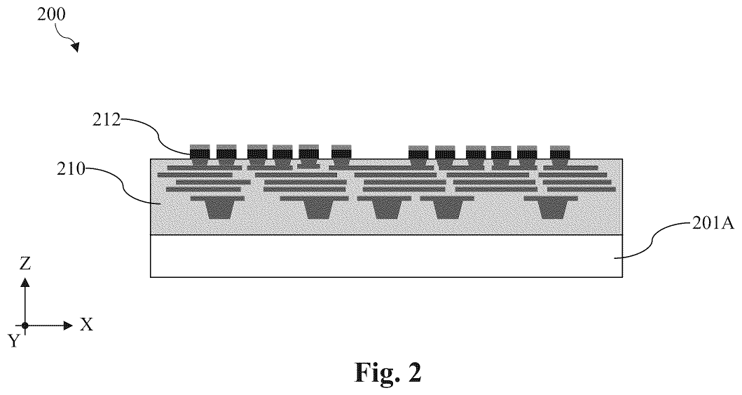

The various aspects of the present disclosure will now be described in more detail with reference to the figures. In that regard, FIG. 1 is a flowchart illustrating methods 100 of forming a package structure on a work-in-progress (WIP) structure 200, according to various aspects of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-19, which are fragmentary cross-sectional views and top views of the WIP structure 200 at dissimilar stages of fabrication according to various embodiments of method 100. Because the WIP structure 200 will be fabricated into a package structure, the WIP structure 200 may be referred to herein as a package structure 200 as the context requires. For avoidance of doubts, the X, Y and Z directions in FIGS. 2-24 are perpendicular to one another. Throughout the present disclosure, unless expressly otherwise described, like reference numerals denote like features.

Referring to FIGS. 1 and 2, method 100 includes a block 102 where an interposer 210 is formed over a first carrier substrate 201A. In some embodiments, the first carrier substrate 201A may be a glass carrier, a ceramic carrier, a semiconductor carrier, or a polymer carrier. While not explicitly shown in the figures, a release film may be deposited over the first carrier substrate 201A before the formation of the interposer 210 thereon. The release film may include a light-to-heat-conversion (LTHC) coating material and may be deposited using a suitable method. As its name suggests, the release film may decompose when heated by light or laser. After deposition of the release film, a plurality of insulation layers and a plurality of redistribution layers (RDLs) are formed. A redistribution layer is formed over the release film using electroplating. In an example process, a seed layer is deposited over the release film using physical vapor deposition (PVD), plasma enhanced chemical vapor deposition (PECVD), or ALD. In some instances, the seed layer may include an adhesion layer and a copper-containing layer. The adhesion layer may include titanium, titanium nitride, tantalum, or tantalum nitride. The copper-containing layer may include copper or an alloy thereof. After the seed layer is deposited, a plating mask is formed over the seed layer using photolithography techniques. The plating mask includes openings that expose the seed layer. A metal, such as copper, aluminum, nickel, cobalt, palladium, may then be deposited on the exposed portions of the seed layer using electroplating or electroless plating. The plating mask is then removed using ashing or chemical stripping. After removal of the exposed seed layer, a redistribution layer is formed. An insulation layer is then deposited over the redistribution layer using spin-on coating or lamination. The insulation layer may include polybenzoxazole (PBO), polyimide (PI), benzocyclobutene (BCB), or alike. The deposited insulation layer is then patterned using photolithography and etching processes such that openings are formed in the insulation layer. Another redistribution layer is then deposited over the patterned insulation layer. This process may repeat until a desired number of redistribution layers is reached. In some embodiments, interposer 210 may include between 3 and 15 redistribution layers and may be referred to as a redistribution structure. At block 102, micro bumps 212 are formed over the interposer 210. Each of the micro bumps 212 includes a metal pillar and a solder feature over the metal pillar. In some implementations, the metal pillar may include copper, aluminum, gold, nickel, silver, palladium, tin, or the like. The solder feature may include tin (Sn), silver (Ag), or a combination thereof.

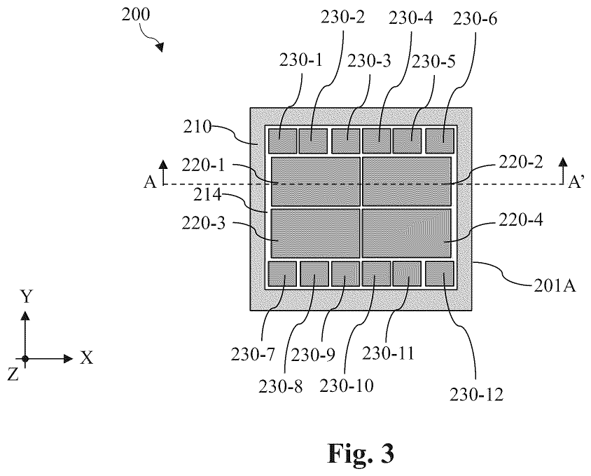

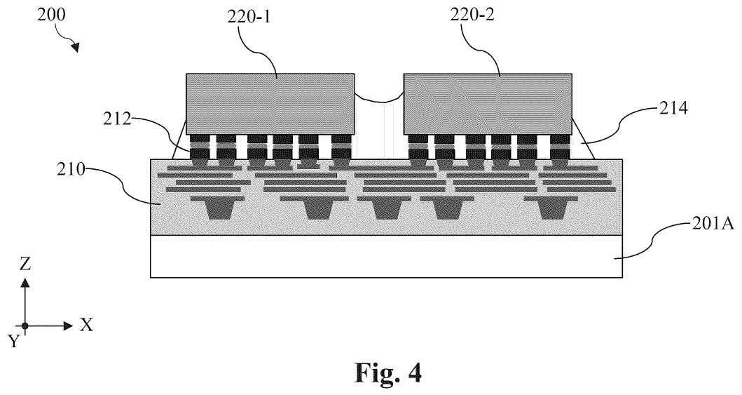

Referring to FIGS. 1, 3 and 4, method 100 includes a block 104 where dies are bonded to a front side of the interposer 210. Reference is first made to FIG. 3, which illustrates a top view the interposer 210. In some embodiments, the dies bonded to the interposer 210 include a plurality of central dies and a plurality of peripheral dies. The central dies include system dies, such as SoC dies or SoIC dies and the peripheral dies include memory dies, electronic dies, or photonic dies. An SoC die may include a graphic processing unit (GPU), a central processing unit (CPU), and a neural processing unit (NPU). An SoIC die may include an SoC die and a secondary die that is bonded to the SoIC and electrically coupled to the SoC by way of a TSV. In the depicted embodiments shown in FIG. 3, the peripheral dies include a first memory die 230-1, a second memory die 230-2, a third memory die 230-3, a fourth memory die 230-4, a fifth memory die 230-5, a sixth memory die 230-6, a seventh memory die 230-7, an eighth memory die 230-8, a nineth memory die 230-9, a tenth memory die 230-10, an eleventh memory die 230-11, and a twelfth memory die 230-12 and the central dies include a first system die 220-1, a second system die 220-2, a third system die 220-3, and a fourth system die 220-4. In some instances, each of the system dies may also be referred to as an SoC die. Each of the memory dies may include a high-bandwidth-memory (HBM) construction. HBM is a computer memory interface that is commonly used in conjunction with high-performance graphics accelerators, high-performance data center, application specific integrated circuit (ASIC) for AI application, on-package cache in CPUs, or high-performance computing ICs. In the depicted embodiments, each of the memory die include a dynamic random access memory (DRAM) stack die (or memory stack die) and a controller die that is bonded to the DRAM stack die. In some instances, the DRAM stack die may include 2 to 10 DRAM dies stacked vertically. The vertical stacking allows for higher bandwidth, smaller power consumption, and smaller form factor. At block 104, the memory dies and the central dies are placed on the front side of the interposer 210 such that the micro bumps 212 are aligned with contact pads on the memory dies and central dies. An anneal process or a bonding process is then performed to bond the memory dies and central dies to the interposer 210. FIG. 4 illustrates a fragmentary cross-section along line A-A′ in FIG. 3. Because line A-A′ cuts across the first system die 220-1 and the second system die 220-2, FIG. 4 shows that the first system die 220-1 and the second system die 220-2 are bonded to the micro bumps 212 on the front side of the interposer 210.

Referring to FIGS. 1, 3 and 4, method 100 includes a block 106 where a first underfill 214 is deposited between the dies and the interposer 210. In some embodiments, the space between the interposer 210 and dies may be filled with a first underfill 214. In some implementations, the first underfill 214 may be a capillary underfill. In an example process, a material for the first underfill 214 is dispensed around the dies and capillary force allows the first underfill 214 to fill the space between the dies and the interposer 210. In some embodiments, the first underfill 214 includes epoxy, fillers, or a combination thereof. As shown in FIG. 4, capillary force allows the first underfill 214 to cover a portion of the sidewalls of the dies (including memory dies 230-1, 230-2, 230-3, 230-4, 230-5, 230-6, 230-7, 230-8, 230-9, 230-10, 230-11, 230-12 and system dies 220-1, 220-2, 220-3, and 220-4). However, as also shown in FIG. 4, the sidewalls of the dies are not completely covered by the first underfill 214.

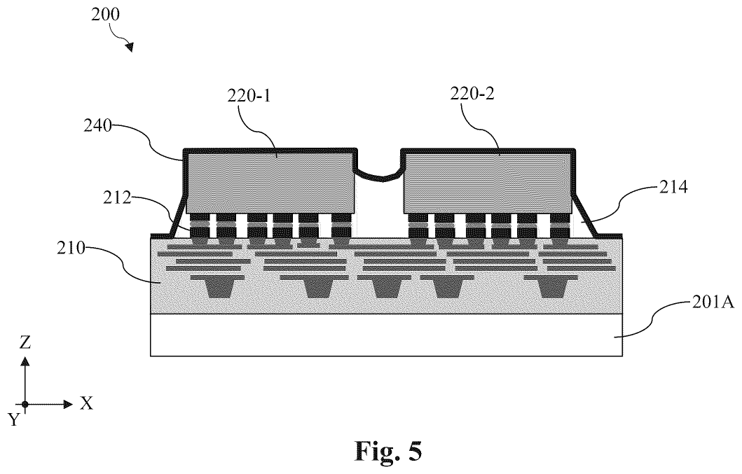

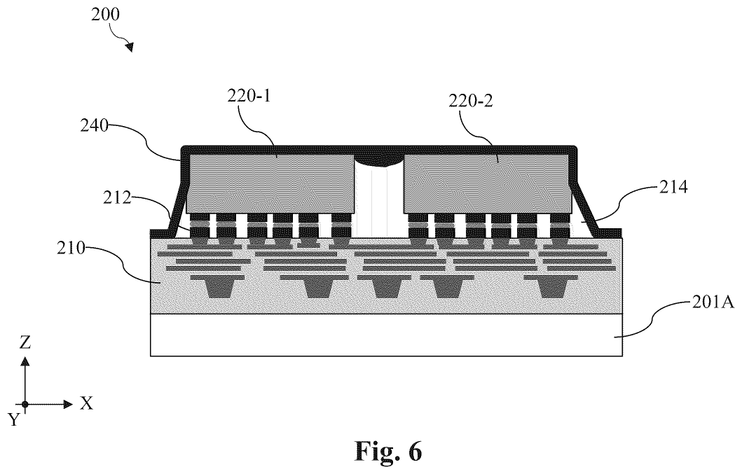

Referring to FIGS. 1, 5 and 6, method 100 includes a block 108 where a metal layer 240 is formed over the dies and the first underfill 214. In some embodiments, the metal layer 240 includes titanium, copper, a titanium copper (TiCu) alloy, copper paste, or gold. At block 108, the metal layer 240 may be deposited over the dies and the first underfill 214 using PVD. In some alternative embodiments, a copper paste may be printed, sprayed, or brushed on the dies and the first underfill 214 and an anneal process may be performed to cure the copper paste to form the metal layer 240. In some instances, the copper paste may include copper particles dispersed in a flowable polymer, such as an acrylic resin. As shown in FIG. 5, the metal layer 240 may conformally extend along surfaces of the interposer 210, sidewalls of the first underfill 214, sidewalls of the dies, and top surfaces of the dies. Additionally, the metal layer 240 may be deposited on the first underfill 214 between two adjacent dies, such as between the first system die 220-1 and the second system die 220-2 along the X direction in FIG. 5. In some embodiments where a top surface of the first underfill 214 is closer to top surfaces of the dies and the metal layer 240 is thicker, the metal layer 240 may completely fill the gap among dies. FIG. 6 illustrates an example where the metal layer 240 completely fills in the gap between the first system die 220-1 and the second system die 220-2. In the embodiments represented in FIG. 6, the metal layer 240 completely covers the first underfill 214 between two adjacent dies, such as two adjacent system dies, two adjacent memory dies, or a system die and an adjacent memory die.

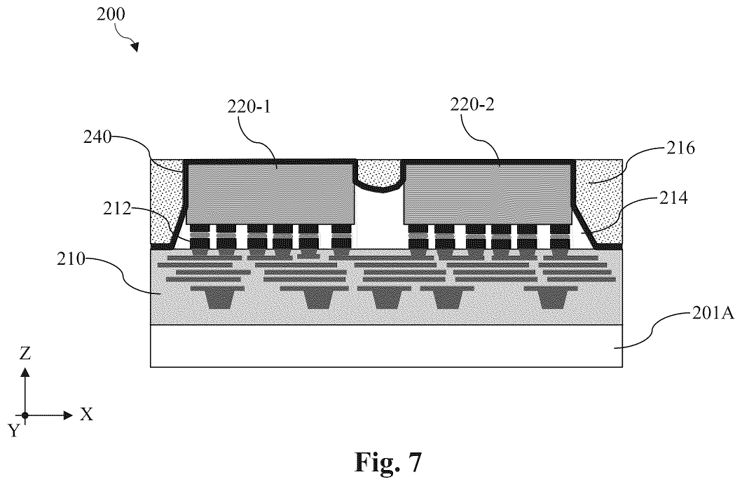

Referring to FIGS. 1 and 7, method 100 includes a block 110 where a first molding material 216 is deposited over the metal layer 240. In some embodiments, the first molding material 216 may include an epoxy, a polymer, a combination thereof. In some implementations, the first molding material 216 may include filler particles, such as silicon oxide particles, metal particles, or ceramic particles to improve the mechanical properties and thermal conductivity of the first molding material 216. The first molding material 216 may be deposited over the metal layer 240 using compression molding, transfer molding, or a suitable molding process. In some instances, a curing step is performed to cure the first molding material 216. The curing step may include use of thermal curing or ultraviolet (UV) curing, or the like. A grinding process and/or a polishing process may be performed to the first molding material 216 to provide a planar top surface.

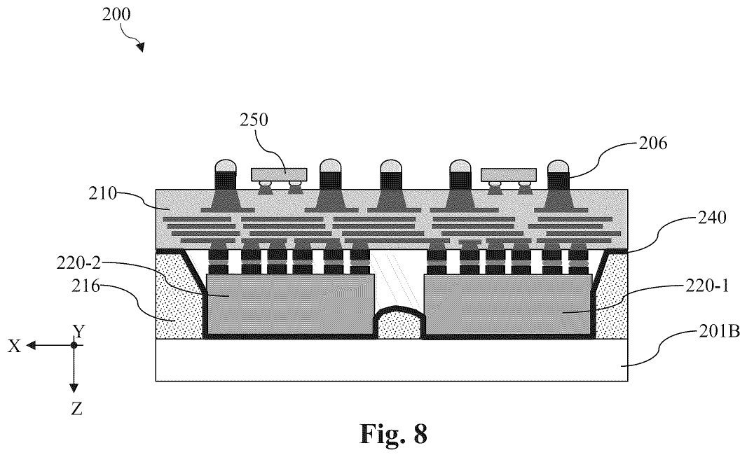

Referring to FIGS. 1 and 8, method 100 includes a block 112 where solder features 206 are formed over a back side of the package structure 200. Because operations at block 112 are performed to a back side of the interposer 210, the interposer 210 is de-bonded from the first carrier substrate 201A and bonded upside down to a second carrier substrate 201B. The second carrier substrate 201B may be similar to the first carrier substrate 201A in terms of thickness and construction. With the WIP structure 200 flipped over and bonded to the second carrier substrate 201B, solder features 206 and passive devices 250 are bonded to the back side of the interposer 210. The solder features 206 are electrically connected to contact pads on the back side of the interposer. In some embodiments, the solder features 206 may include ball grid array (BGA) connectors, solder balls, metal pillars, controlled collapse chip connection (C4) bumps, micro bumps, electroless nickel-electroless palladium-immersion gold technique (ENEPIG) formed bumps, or the like. In one embodiment, the solder features 206 include C4 bumps that may include lead, tin, silver, or alloy thereof. The passive devices 250 may include capacitors, resistors, or inductors. Because the passive devices 250 are disposed on the back side and integrated with the interposer 210, they may be referred to as integrated passive devices (IPDs) 250 or land-side integrated passive devices (LSIPDs) 250. To bond the passive devices 250 to the back side of the interposer 210, they are placed over contact pads and then an anneal or a reflow process is performed to bond the passive devices 250 on the back side of the interposer 210.

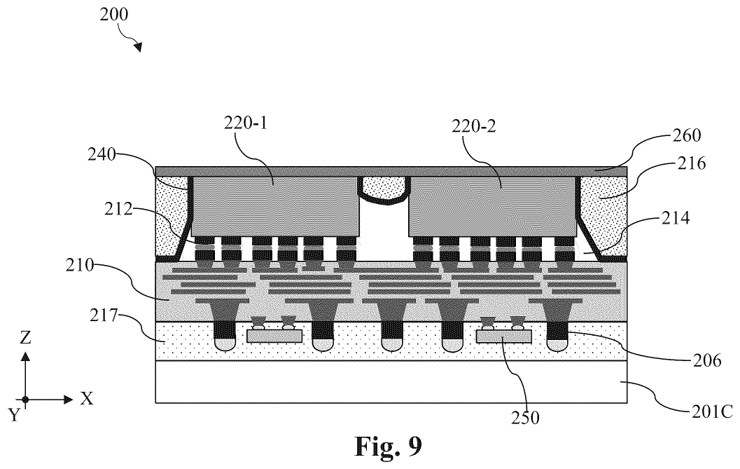

Referring to FIGS. 1 and 9, method 100 may optionally include a block 114 where a thermal interface material (TIM) 260 is deposited over the dies and the first molding material 216. Operations at block 114 are optional. Operations at block 114 deposit the TIM 260 before the interposer 210 is bonded to a package substrate. As will be described in more detail below, in some alternative embodiments, the TIM 260 is not deposited before the interposer 210 is bonded to a package substrate. Instead, a thicker or a different thermal interface material (TIM) layer is deposited over the top surfaces of the dies after the interposer 210 is bonded to the package substrate. In those alternative embodiments, operations at block 114 are omitted.

As shown in FIG. 9, block 114 deposits the TIM 260 over top surfaces of the dies and the first molding material 216. This requires first forming an adhesive material 217 over the solder features 206 and the passive devices 250. The adhesive material 217 may include silicone, nylon, polyetheretherketone (PEEK), epoxy, or resin. After the formation of the adhesive material 217, a grinding process and/or a polishing process is performed to provide a planar surface. The planar surface of the adhesive material 217 is then bonded to a third carrier substrate 201C. The third carrier substrate 201C may be similar to the first carrier substrate 201A in terms of thickness and construction. The second carrier substrate 201B is then de-bonded and removed. In some embodiments, a chemical mechanical polishing (CMP) or a grinding process is performed after the de-bonding of the second carrier substrate 201B to remove the metal layer 240 on the top surfaces of the dies.

For purpose of the present disclosure, TIM refers to materials that are placed between an electronic device and a heat sink to improve heat dissipation of the electronic device. At block 114, the TIM 260 may be applied in a gel form, as a metal layer, or as a pre-cut tape. In some embodiments, the TIM 260 may include boron nitride, graphene, graphite, aluminum (Al), titanium (Ti), nickel-vanadium (NiV), gold (Au), or a combination thereof. In one embodiment, the TIM 260 may include aluminum (Al), titanium (Ti), nickel-vanadium (NiV), gold (Au), or an alloy thereof. The formation of the TIM 260 at block 114 may be referred to as a backside metallization process.

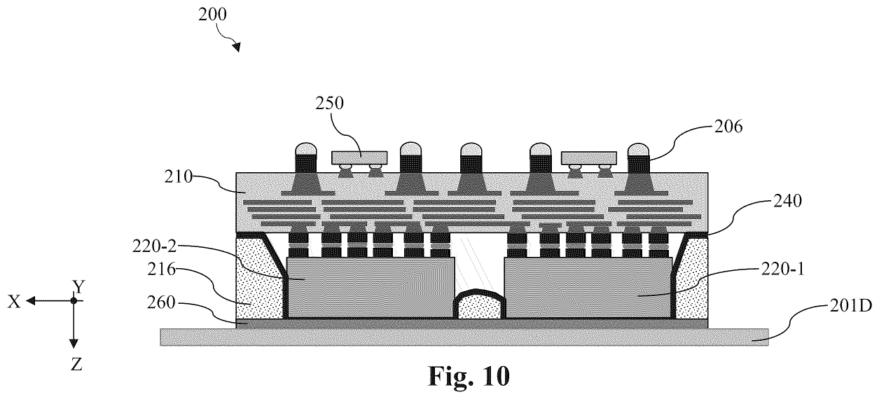

Referring to FIGS. 1 and 10, method 100 includes a block 116 where the package structure 200 is singulated. At block 116, the interposer 210, along with the dies bonded thereon, is de-bonded from the third carrier substrate 201C and mounted on a fourth carrier substrate 201D with the TIM 260 facing down. In some embodiments, the fourth carrier substrate 201D may be a carrier tape. In these embodiments, the fourth carrier substrate 201D may include a polymer, such as polycarbonate. As shown in FIG. 10, the adhesive material 217 is selectively removed to expose the solder feature 206 and the passive devices 250. The WIP structure 200 is then subject to a die sawing or singulation process such that each of the package components is singulated. As used herein, a package component includes the interposer 210, dies bonded to the interposer 210, the first molding material 216, the metal layer 240, the TIM 260, the solder features 206, and the passive devices 250.

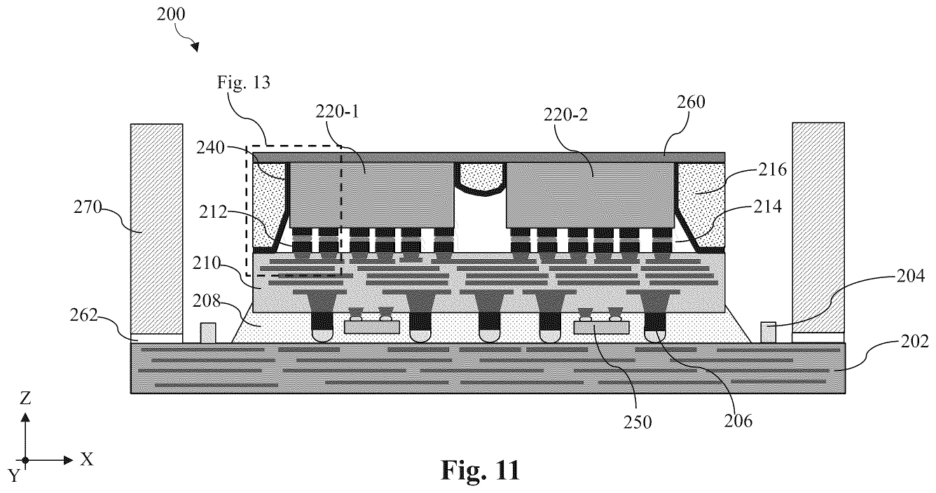

Referring to FIGS. 1 and 11, method 100 includes a block 118 where the interposer 210 is bonded to a package substrate 202. In some embodiments, the package substrate 202 may include a printed circuit board (PCB) or the like. While not explicitly shown in the features, the package substrate 202 may include through-substrate vias (TSVs) or through hole connectors that extend from the front side surface 202F to the back side surface 202B of the package substrate 202. Additionally, in order to electrically couple to the package component, the package substrate 202 may include a plurality of contact pads over the front side surface 202F. In order to electrically couple to solder features 206, the package substrate 202 may also include a plurality of contact pads. At least one passive component 204 may be bonded on the package substrate 202. The at least one passive component 204 may include a capacitor or a resistor. At block 118, the solder features 206 are aligned with contact pads on the package substrate 202 and an anneal process is performed to bond the solder features 206 to the contact pads.

Referring to FIGS. 1 and 11, method 100 includes a block 120 where a second underfill 208 formed between the interposer 210 and the package substrate 202. In some embodiments, the space between the interposer 210 and the package substrate 202 may be filled with a second underfill 208. In some implementations, the second underfill 208 may be a capillary underfill. In an example process, a material for the second underfill 208 is dispensed around the bonded package component and capillary force allows the second underfill 208 to fill the space between the interposer 210 and the package substrate 202. In some embodiments, the second underfill 208 includes epoxy, fillers, or a combination thereof. As shown in FIG. 10, capillary force allows the second underfill 208 to cover the solder features 206 and the passive devices 250. Additionally, capillary force may cause a portion to the second underfill 208 to contact a portion of the sidewalls of the interposer 210.

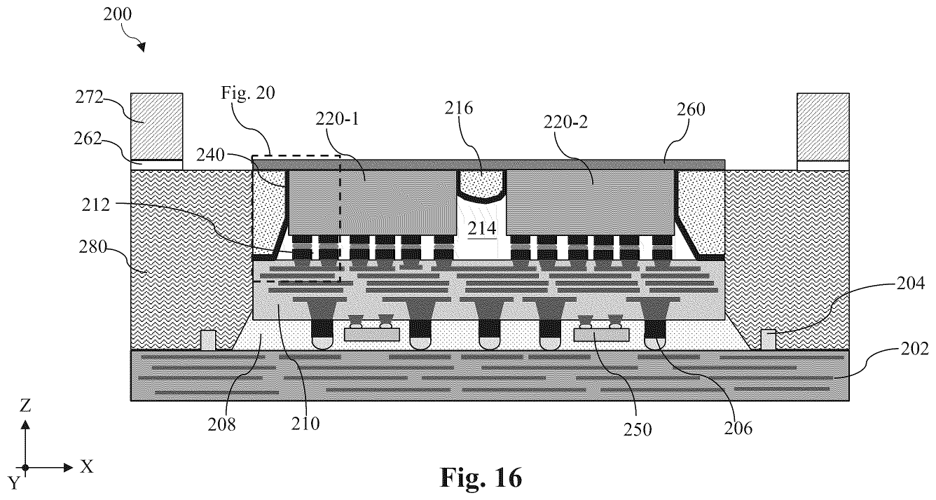

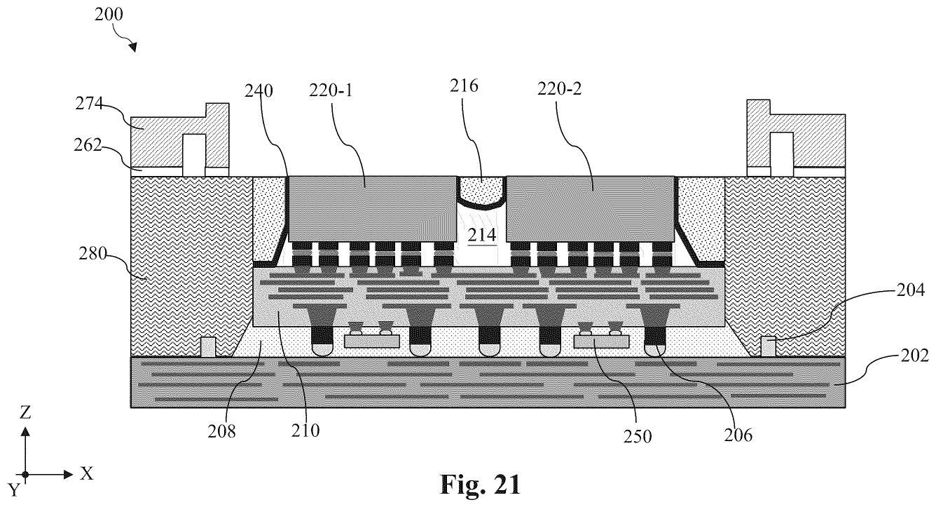

Referring to FIGS. 1 and 11-24, method 100 includes a block 122 where further processes are performed. The further processes include forming protective structures and heat dissipation structures around the interposer 210 and the dies. In embodiments represented in FIGS. 11-15, block 122 attaches a first ring structure 270 to the package substrate 202. In some embodiments represented in FIGS. 16-20, block 122 forms an on-substrate molding material 280 over the package substrate 202 and around the package component and attaches a second ring structure 272 to the on-substrate molding material 280. In still some embodiments represented in FIGS. 21-24, block 122 forms an on-substrate molding material 280 over the package substrate 202 and around the package component, attaches a third ring structure 274 to the on-substrate molding material 280, forms a TIM structure 290 within the third ring structure 274, and attaches a lid 276 over the third ring structure 274 and the TIM structure 290.

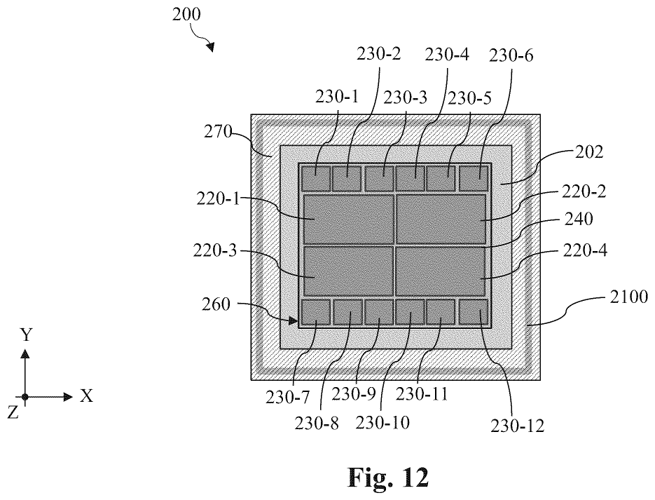

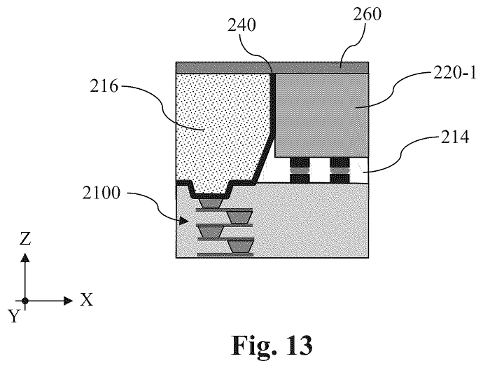

Reference is first made to FIGS. 11-15. In some embodiments, a first ring structure 270 is attached to the package substrate 202 to stiffen the package structure 200. Referring to FIG. 11, at block 122, the first ring structure 270 is placed over the package substrate 202 and attached to the package substrate 202 by way of adhesive 262. In some embodiments, the first ring structure 270 may be formed of a metal or an alloy, such as aluminum (Al), copper (Cu), iron (Fe), nickel (Ni), cobalt (Co), or an alloy thereof. Example alloys may include an aluminum-copper alloy, an iron-nickel alloy, or an iron-nickel-cobalt alloy. In some embodiments, a top surface of the first ring structure 270 is higher than a top surface of the TIM 260. The adhesive 262 may include silicone, nylon, polyetheretherketone (PEEK), epoxy, or resin. In a top view shown in FIG. 12, the first ring structure 270 extends continuously around the package component that includes the interposer 210 and the dies (including memory dies 230-1, 230-2, 230-3, 230-4, 230-5, 230-6, 230-7, 230-8, 230-9, 230-10, 230-11, 230-12 and system dies 220-1, 220-2, 220-3, and 220-4) bonded thereon. In the depicted embodiments, the inner sidewall of the first ring structure 270 is spaced apart from sidewalls of the interposer 210, the first molding material 216, and the TIM 260. A dotted line area in FIG. 11 is enlarged and shown in FIG. 13. In some embodiments, a portion of the metal layer 240 is in physical and electrical contact with a seal ring structure 2100 in the interposer 210. As illustrated in the top see-through view in FIG. 12, the seal ring structure 2100 vertically extends though the interposer 210 and extends continuously along the edge of the interposer 210 to prevent moisture ingress. Like the redistribution layers in the interposer 210, the seal ring structure 2100 includes titanium, titanium nitride, tantalum, tantalum nitride, copper, an alloy of copper, aluminum, nickel, cobalt, palladium, or a combination thereof. In some implementations, the seal ring structure 2100 is electrically floating and is not connected to any of the redistribution layers in the interposer 210. In some other implementations, the seal ring structure 2100 is not connected to any of the redistribution layers in the interposer 2100 but is coupled to a ground potential. The connection between the metal layer 240 and the seal ring structure 2100 helps direct heat down ward either into the interposer 210 or into further grounding structure.

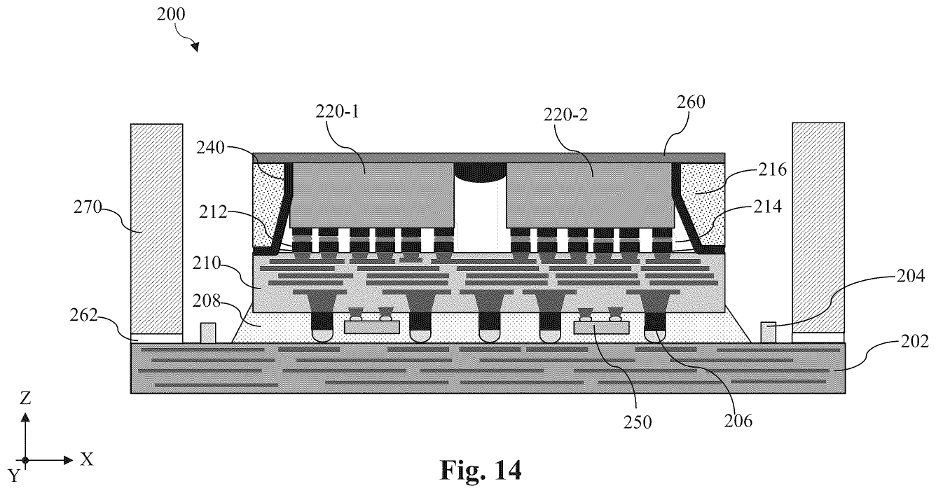

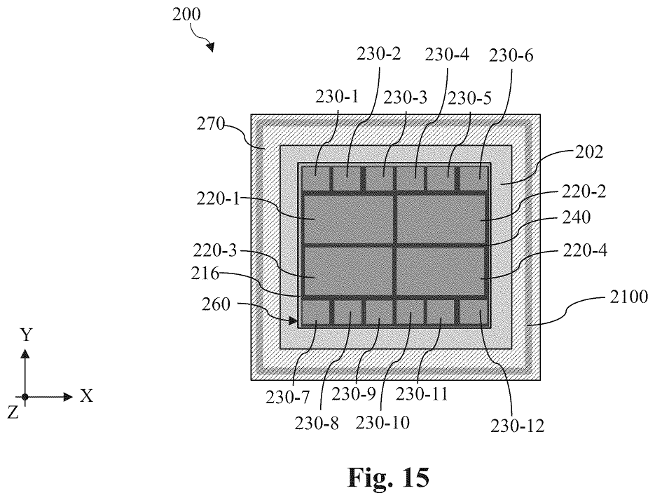

FIGS. 14 and 15 illustrate embodiments where the metal layer 240 completely fills the gaps between two adjacent dies. In FIG. 14, the metal layer 240 completely fills the gap between the first system die 220-1 and the second system die 220-2. The metal layer 240 promotes heat conduction between the dies and the TIM 260 as well as heat conduction between the dies and the seal ring structure (e.g., the seal ring structure 2100 shown in FIG. 13). In a top view shown in FIG. 15, the metal layer 240 fills the gaps between two adjacent dies. The first molding material 216 around the edges of the interposer 210 interfaces the TIM 260.

Reference is then made to FIGS. 16-20. Referring to FIG. 16, at block 122, an on-substrate molding material 280 may be first deposited over the package substrate 202 and around the package component (which includes the interposer 210, the dies, the first molding material 216) and then a second ring structure 272 may be attached to the on-substrate molding material 280 by way of an adhesive 262 to stiffen the structure. In some embodiments, the on-substrate molding material 280 may include an epoxy, a polymer, a combination thereof. In some implementations, the on-substrate molding material 280 may include filler particles, such as silicon oxide particles, metal particles, or ceramic particles to improve the mechanical properties and thermal conductivity of the on-substrate molding material 280. The on-substrate molding material 280 may be deposited over the package substrate 202 and the passive component 204 using compression molding, transfer molding, or a suitable molding process. In some instances, a curing step is performed to cure the on-substrate molding material 280. The curing step may include use of thermal curing or ultraviolet (UV) curing, or the like. A grinding process and/or a polishing process may be performed to the on-substrate molding material 280 to provide a planar top surface. In some embodiments, the second ring structure 272 may be formed of a metal or an alloy, such as aluminum (Al), copper (Cu), iron (Fe), nickel (Ni), cobalt (Co), or an alloy thereof. Example alloys may include an aluminum-copper alloy, an iron-nickel alloy, or an iron-nickel-cobalt alloy. In some embodiments, a top surface of the second ring structure 272 is higher than a top surface of the TIM 260. The adhesive 262 may include silicone, nylon, polyetheretherketone (PEEK), epoxy, or resin.

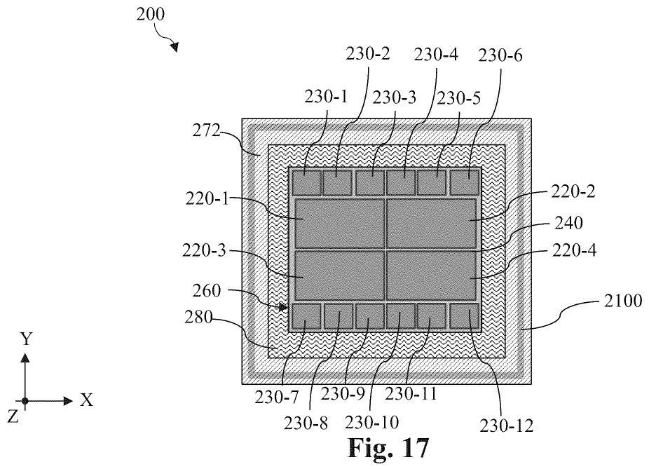

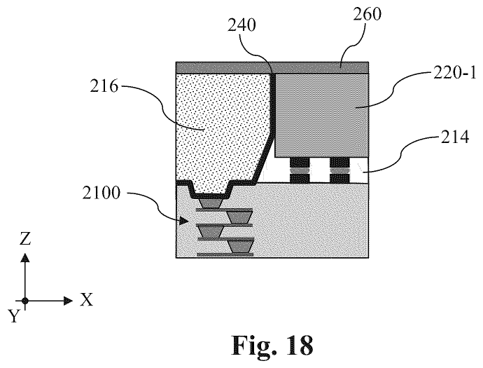

In a top view shown in FIG. 17, the on-substrate molding material 280 covers sidewalls of the interposer 210 and the dies (including memory dies 230-1, 230-2, 230-3, 230-4, 230-5, 230-6, 230-7, 230-8, 230-9, 230-10, 230-11, 230-12 and system dies 220-1, 220-2, 220-3, and 220-4) bonded thereon. The second ring structure 272 is attached to the top surface of the on-substrate molding material 280. When viewed along the vertical direction (i.e., the Z direction), the on-substrate molding material 280 extends around the interposer 210 and the dies bonded thereon. The second ring structure 272, which is attached to the top surface of the on-substrate molding material 280, extends around a vertical projection area of the interposer 210 and the dies. A dotted line area in FIG. 16 is enlarged and shown in FIG. 18. In some embodiments, a portion of the metal layer 240 is in physical and electrical contact with a seal ring structure 2100 in the interposer 210. As illustrated in the top see-through view in FIG. 17, the seal ring structure 2100 vertically extends though the interposer 210 and extends continuously along the edge of the interposer 210 to prevent moisture ingress. Like the redistribution layers in the interposer 210, the seal ring structure 2100 includes titanium, titanium nitride, tantalum, tantalum nitride, copper, an alloy of copper, aluminum, nickel, cobalt, palladium, or a combination thereof. In some implementations, the seal ring structure 2100 is electrically floating and is not connected to any of the redistribution layers in the interposer 210. In some other implementations, the seal ring structure 2100 is not connected to any of the redistribution layers in the interposer 2100 but is coupled to a ground potential. The connection between the metal layer 240 and the seal ring structure 2100 helps direct heat downward either into the interposer 210 or into further grounding structure.

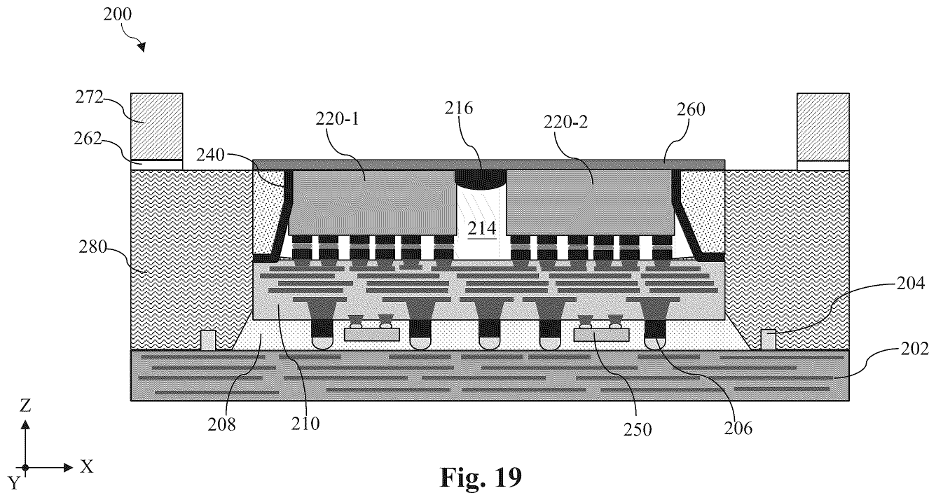

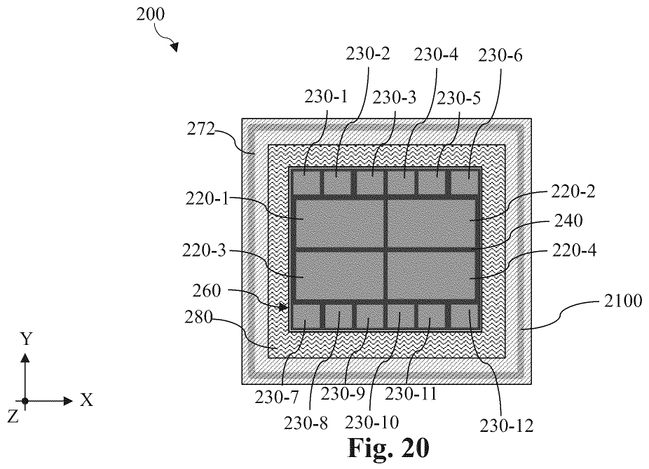

FIGS. 19 and 20 illustrate embodiments where the metal layer 240 completely fills the gaps between two adjacent dies. In FIG. 19, the metal layer 240 completely fills the gap between the first system die 220-1 and the second system die 220-2. The metal layer 240 promotes heat conduction between the dies and the TIM 260 as well as heat conduction between the dies and the seal ring structure (e.g., the seal ring structure 2100 shown in FIG. 18). In a top view shown in FIG. 20, the metal layer 240 fills the gaps between two adjacent dies. The first molding material 216 around the edges of the interposer 210 interfaces the TIM 260.

Reference is now made to FIGS. 21-24. As described above, in some embodiments, operations at block 114 are omitted and the TIM 260 is not formed over top surfaces of the dies, the first molding material 216, and the metal layer 240, the package component (including the interposer 210, the dies, and the passive devices 250). At block 116, the interposer 210, along with the dies bonded thereon, is de-bonded from the second carrier substrate 201B (shown in FIG. 7) and the WIP structure 200 is then subject to a die sawing or singulation process such that each of the package components is singulated. At block 118, the interposer 210, along with the dies bonded thereon, is bonded to a package substrate 202. At block 118, the solder features 206 are aligned with contact pads on the package substrate 202 and an anneal process is performed to bond the solder features 206 to contact pads on the package substrate 202. At block 120, the space between the interposer 210 and package substrate 202 is filled with the second underfill 208. At block 122, the on-substrate molding material 280 may be deposited over the package substrate 202 and the passive component 204 using compression molding, transfer molding, or a suitable molding process. A curing step may be performed to the on-substrate molding material 280. Thereafter, a grinding process and/or a polishing process may be performed to the on-substrate molding material 280 to provide a planar top surface. In some embodiments represented in FIG. 21, top surfaces of the on-substrate molding material 280, the first molding material 216, the dies, and the metal layer 240 may be coplanar.

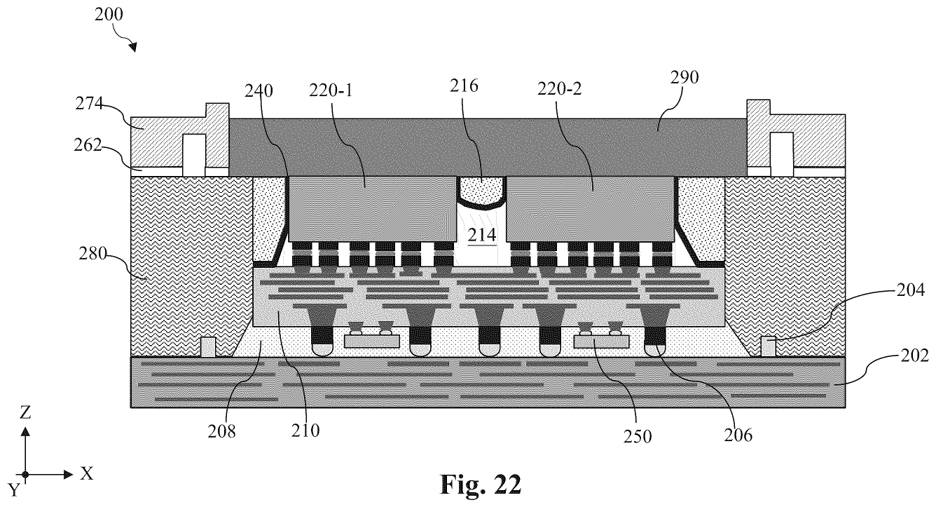

Referring still to FIG. 22, at block 122, a third ring structure 274 is attached to the top surface of the on-substrate molding material 280 by way of an adhesive 262 to stiffen the structure. In some embodiments represented in FIG. 22, the third ring structure 274 has an h-shaped cross-section to provide mechanical strength and rigidity. Like the first ring structure 270 and the second ring structure 272, the third ring structure 274 may be formed of a metal or an alloy, such as aluminum (Al), copper (Cu), iron (Fe), nickel (Ni), cobalt (Co), or an alloy thereof. Example alloys may include an aluminum-copper alloy, an iron-nickel alloy, or an iron-nickel-cobalt alloy. The adhesive 262 may include silicone, nylon, polyetheretherketone (PEEK), epoxy, or resin. Along the vertical direction (i.e., the Z direction), the third ring structure 274 extends around a vertical projection area of the dies and the interposer 210. Referring now to FIG. 22, a TIM structure 290 is deposited in the area surrounded by the third ring structure 274. In some embodiments represented in FIG. 22, the TIM structure 290 interfaces top surfaces of the on-substrate molding material 280, the first molding material 216, the metal layer 240, and the dies (including memory dies 230-1, 230-2, 230-3, 230-4, 230-5, 230-6, 230-7, 230-8, 230-9, 230-10, 230-11, 230-12 and system dies 220-1, 220-2, 220-3, and 220-4), as well as sidewalls of the third ring structure 274. The TIM structure 290 is in a gel form and may include thermally conductive particles dispersed in a silicone gel, an acrylic gel, a polyolefin gel, or other polymer gel. As deposited, the TIM structure 290 is thicker than the TIM 260 to provide a volume. In some embodiments, a thickness of the TIM structure 290 is between 5 times to about 100 times of a thickness of the TIM 260. The volume of the TIM structure 290 allows it to deform and reduce stress exerted on the dies. As will be described further below, the third ring structure 274 and a lid 276 (to be described further below) define a space greater than the volume of the TIM structure 290 such that the TIM structure 290 may deform within the defined space. As compared to the TIM structure 290, the TIM 260 only provides a thermally conductive interface and it is not intended to deform or absorb stress exerted on the dies. In order to preserve the flowability of the TIM structure 290, the TIM structure 290 may not be fully cured. In some instances, the TIM structure 290 is either not cured or partially cured such that the TIM structure 290 exhibits greater flowability at an increased temperature.

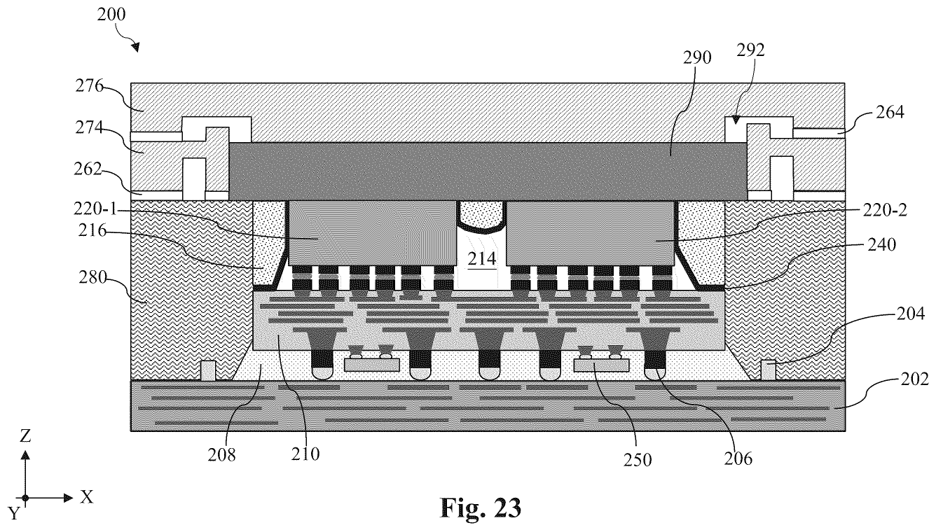

Referring to FIG. 23, at block 122, a lid 276 is attached to the third ring structure 274 to interface a top surface of the TIM structure 290. A composition of the lid 276 is similar to the composition of the third ring structure 274. That is, the lid 276 may be formed of a metal or an alloy, such as aluminum (Al), copper (Cu), iron (Fe), nickel (Ni), cobalt (Co), or an alloy thereof. The lid 276 may be attached to the third ring structure 274 by way of adhesive 264, which may be similar to the adhesive 262. In order to ensure good thermal conduction interface between the TIM structure 290 and the lid 276, a center portion of the lid 276 may partially extend into the space surrounded by the third ring structure 274. The lid 276 includes a ring-shaped recess to accommodate the third ring structure 274 and to provide an expansion room 292. The expansion room 292 accommodate deformation of the TIM structure 290 and prevents excessive stress exerted on the dies.

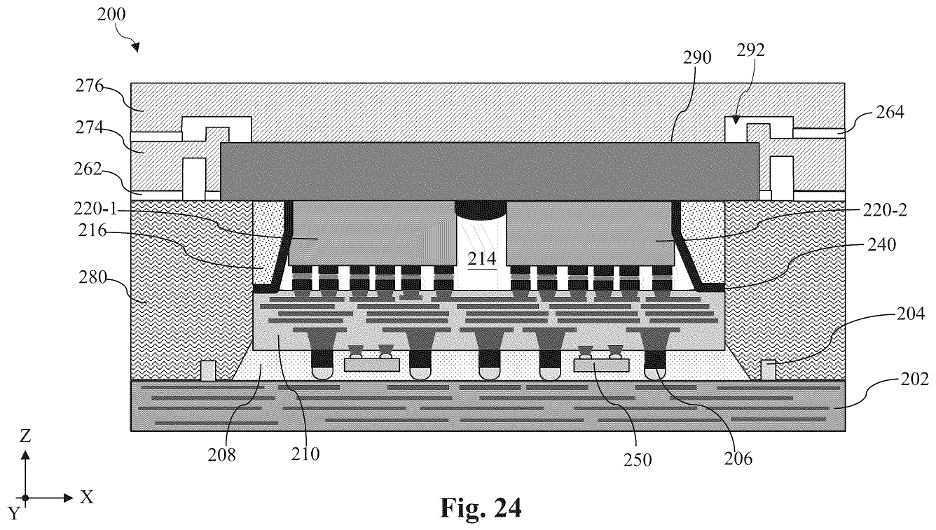

FIG. 24 illustrates an embodiment where the metal layer 240 completely fills the gaps between two adjacent dies under the TIM structure 290. In FIG. 24, the metal layer 240 completely fills the gap between the first system die 220-1 and the second system die 220-2. The metal layer 240 promotes heat conduction between the dies and the TIM structure 290 as well as heat conduction between the dies and the seal ring structure (e.g., the seal ring structure 2100 shown in FIG. 18).

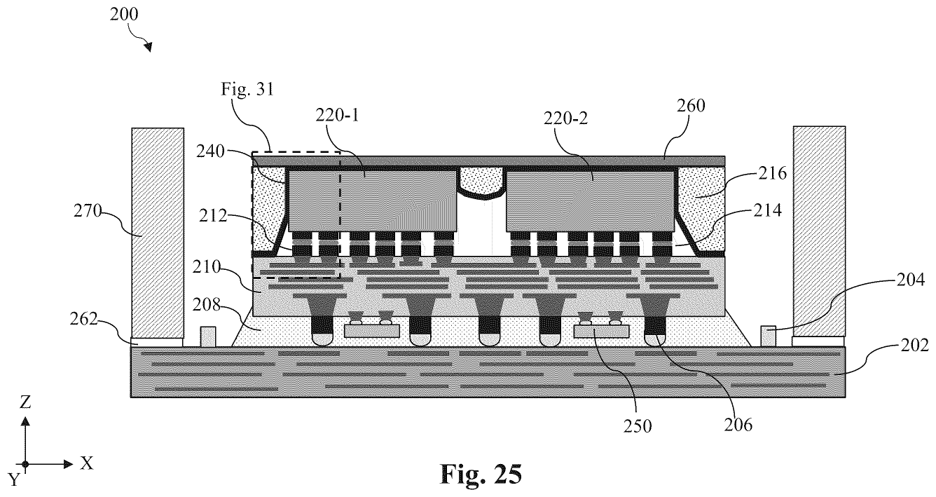

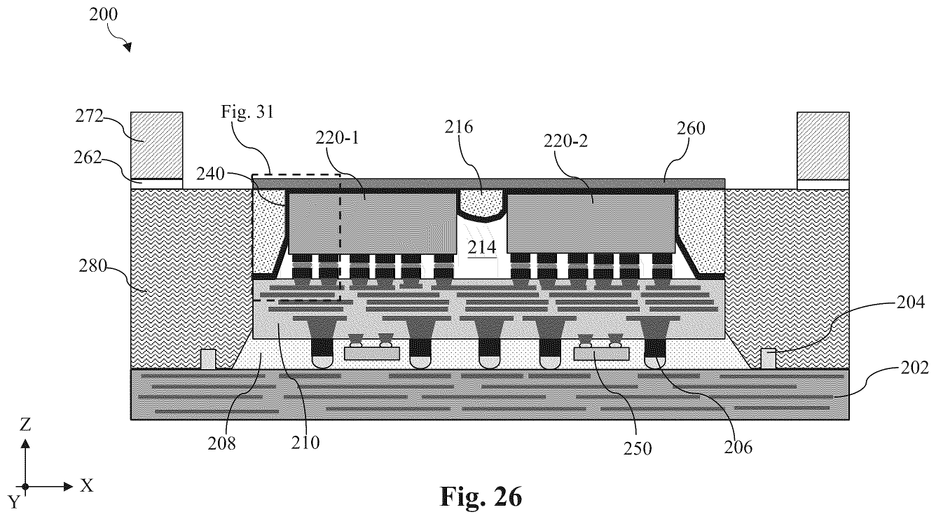

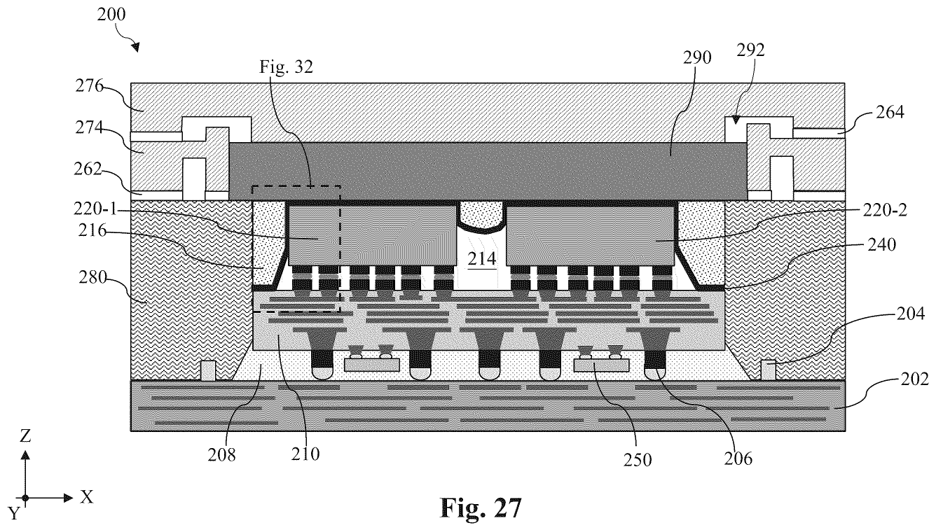

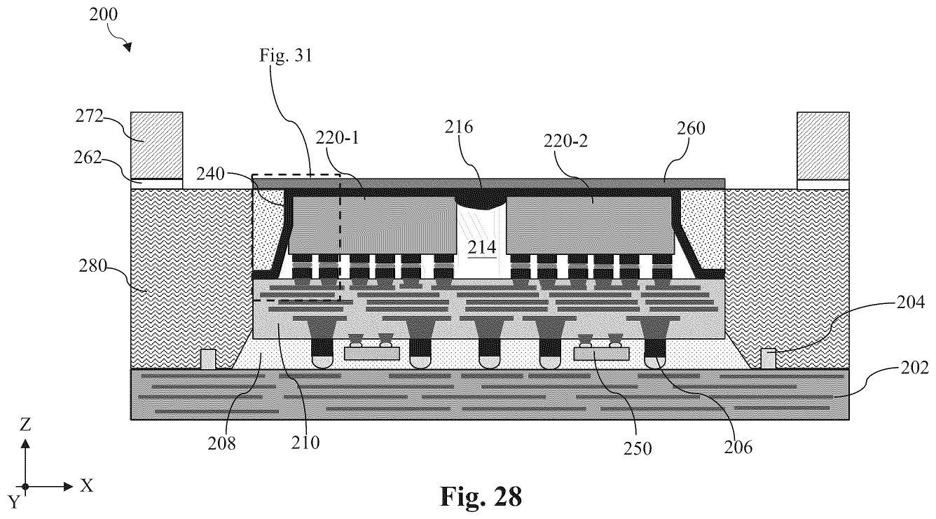

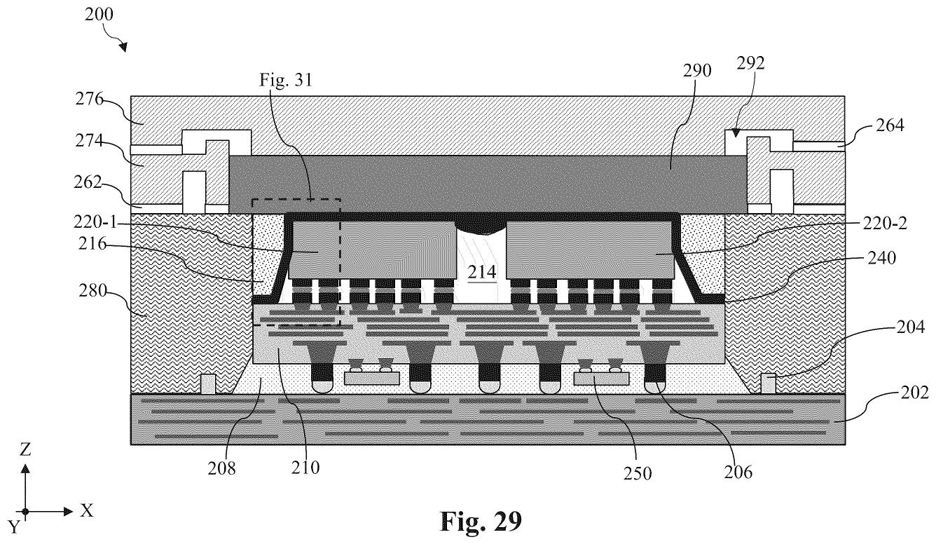

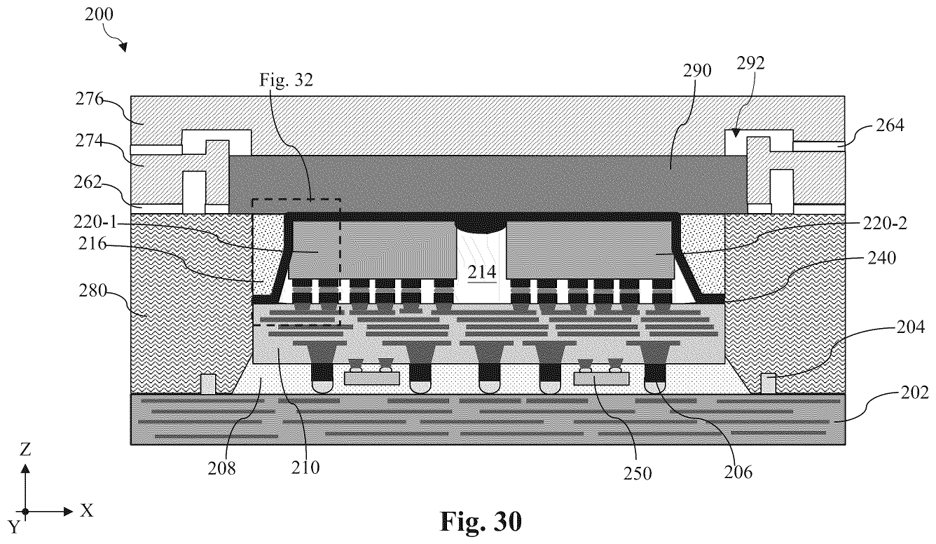

FIGS. 25-32 illustrate alternative embodiments where the metal layer 240 remains on the top surfaces of the dies to interface the TIM 260. As described above with respect to the operations at block 114, a CMP process or a grinding process may be performed to remove the metal layer 240 on the top surfaces of the dies before deposition of the TIM 260. In the alternative embodiments shown in FIGS. 25-32, the metal layer 240 on the top surfaces of the dies is not removed and top surfaces of the dies remain covered by the metal layer 240. As a result, a portion of the metal layer 240 is sandwiched between the dies and the TIM 260 or between the dies and the TIM structure 290. In embodiments represented in FIG. 25, the first ring structure 270 is attached to the package substrate 202 to surround the interposer 210 and the dies bonded thereon. The metal layer 240 continuously extends along the top surface of the interposer 210, top surfaces of the dies, sidewalls of the first underfill 214, and sidewalls of the dies. In embodiments represented in FIG. 26, the on-substrate molding material 280 is deposited over the package substrate 202 to surround the interposer 210 and the dies, and the second ring structure 272 is attached to the top surface of the on-substrate molding material 280. The metal layer 240 continuously extends along the top surface of the interposer 210, top surfaces of the dies, sidewalls of the first underfill 214, and sidewalls of the dies. In embodiments represented in FIG. 27, the on-substrate molding material 280 is deposited over the package substrate 202 to surround the interposer 210 and the dies, the third ring structure 274 is attached to the top surface of the on-substrate molding material 280, and the lid 276 is attached to the third ring structure 274 to interface the TIM structure 290. The metal layer 240 continuously extends along the top surface of the interposer 210, top surfaces of the dies, sidewalls of the first underfill 214, and sidewalls of the dies. FIG. 28 illustrates an embodiment similar to that in FIG. 25 but the metal layer 240 completely fills the gaps among dies. FIG. 29 illustrates an embodiment similar to that in FIG. 26 but the metal layer 240 completely fills the gaps among dies. FIG. 30 illustrates an embodiment similar to that in FIG. 27 but the metal layer 240 completely fills the gaps among dies.

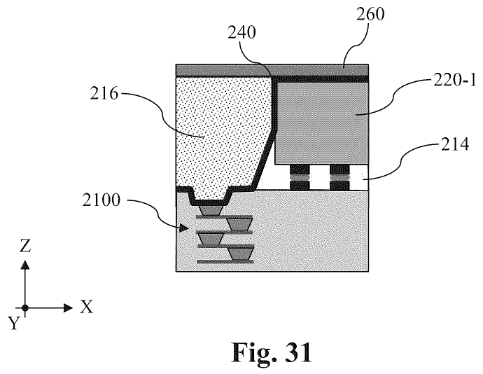

The dotted area in FIG. 25, 26, 28, or 29 is enlarged and illustrated in FIG. 31. In some embodiments, a portion of the metal layer 240 is in physical and electrical contact with a seal ring structure 2100 in the interposer 210. The seal ring structure 2100 vertically extends though the interposer 210 and extends continuously along the edge of the interposer 210 to prevent moisture ingress. As shown in FIG. 31, top surfaces of the dies are spaced apart from the TIM 260 by the portion of the metal layer 240 on the top surfaces of the dies.

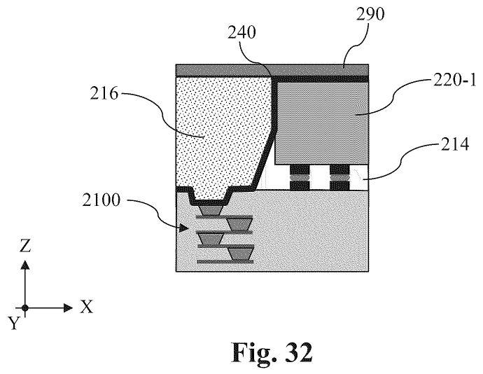

The dotted area in FIG. 27 or 30 is enlarged and illustrated in FIG. 32. In some embodiments, a portion of the metal layer 240 is in physical and electrical contact with a seal ring structure 2100 in the interposer 210. The seal ring structure 2100 vertically extends though the interposer 210 and extends continuously along the edge of the interposer 210 to prevent moisture ingress. As shown in FIG. 32, top surfaces of the dies are spaced apart from the TIM structure 290 by the portion of the metal layer 240 on the top surfaces of the dies.

The present disclosure provides many embodiments. In one aspect, the present disclosure provides a package structure. The package structure includes a package substrate, an interposer bonded to the package substrate, a first die and a second die bonded to the interposer by way of micro bumps, an underfill surrounding the micro bumps, disposed between the first die and the interposer as well as between the second die and the interposer, a metal layer interfacing the interposer, the underfill, sidewalls of the first die, and sidewalls of the second die, a molding material over the metal layer, and a thermal interface material disposed over the molding material, the metal layer, the first die, and the second die.

In some embodiments, the metal layer interfaces a top surface of the interposer. In some implementations, the molding material is spaced apart from the sidewalls of the first die and the sidewalls of the second die by the metal layer. In some instances, the molding material is spaced apart from the underfill by the metal layer. In some embodiments, the thermal interface material interfaces top surfaces of the molding material and the metal layer. In some implementations, the metal layer includes titanium-copper, copper, or gold. In some embodiments, the first die and the second die are spaced apart along a direction and the first die and the second die are spaced apart from one another by the underfill, the metal layer, and the molding material. In some embodiments, the interposer includes a plurality of polymeric layers, a redistribution structure disposed in the plurality of polymeric layers, and a seal ring structure disposed in the plurality of polymeric layers and continuously surrounding the redistribution structure. In some embodiments, the metal layer is physically coupled to the seal ring structure.

In another aspect, the present disclosure provides a package structure. The package structure includes a package substrate, an interposer bonded to the package substrate by way of first-type bumps, a first underfill surrounding the first-type bumps, a first die and a second die bonded to the interposer by way of second-type bumps, a second underfill surrounding the second-type bumps, a metal layer interfacing the interposer, the second underfill, sidewalls of the first die, and sidewalls of the second die, a first molding material over the metal layer, a thermal interface material disposed over the first molding material, the metal layer, the first die, and the second die, and a second molding material over the package substrate and surrounding the first underfill and the first molding material.

In some embodiments, the metal layer includes titanium-copper, copper, or gold. In some embodiments, the second molding material interfaces the metal layer and the first underfill. In some embodiments, a top surface of the second molding material is free of the thermal interface material. In some embodiment, the package structure further includes a metal ring attached to a top surface of the second molding material. In some instances, the metal ring includes aluminum (Al), copper (Cu), iron (Fe), nickel (Ni), cobalt (Co), or an alloy thereof.

In still another aspect, the present disclosure provides a package structure. The package structure includes a package substrate, an interposer bonded to the package substrate by way of first-type bumps, a first underfill surrounding the first-type bumps, a first die and a second die bonded to the interposer by way of second-type bumps, a second underfill surrounding the second-type bumps, a metal layer interfacing the interposer, the second underfill, sidewalls of the first die, and sidewalls of the second die, a first molding material over the metal layer, a second molding material over the package substrate and surrounding the first underfill and the first molding material, and a thermal interface material disposed over the first molding material, the second molding material, the metal layer, the first die, and the second die. The metal layer includes titanium-copper, copper, or gold.

In some embodiments, the package structure further includes a metal ring attached to a top surface of the second molding material. In some embodiments, the thermal interface material interfaces an inner sidewall of the metal ring. In some instances, the thermal interface material includes aluminum, titanium, nickel-vanadium (NiV), or gold. In some embodiments, the second molding material interfaces the metal layer and the first underfill.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
an interposer bonded to the package substrate;
a first die and a second die bonded to the interposer by way of micro bumps;
an underfill surrounding the micro bumps, disposed between the first die and the interposer as well as between the second die and the interposer;
a metal layer interfacing the interposer, the underfill, sidewalls of the first die, and sidewalls of the second die;
a molding material over the metal layer; and
a thermal interface material disposed over the molding material, the metal layer, the first die, and the second die.

2. The package structure of claim 1, wherein the metal layer interfaces a top surface of the interposer.

3. The package structure of claim 1, wherein the molding material is spaced apart from the sidewalls of the first die and the sidewalls of the second die by the metal layer.

4. The package structure of claim 1, wherein the molding material is spaced apart from the underfill by the metal layer.

5. The package structure of claim 1, wherein the thermal interface material interfaces top surfaces of the molding material and the metal layer.

6. The package structure of claim 1, wherein the metal layer comprises titanium-copper, copper, or gold.

7. The package structure of claim 1,
wherein the first die and the second die are spaced apart along a direction,
wherein the first die and the second die are spaced apart from one another by the underfill, the metal layer, and the molding material.

8. The package structure of claim 1, wherein the interposer comprises:
a plurality of polymeric layers;
a redistribution structure disposed in the plurality of polymeric layers; and
a seal ring structure disposed in the plurality of polymeric layers and continuously surrounding the redistribution structure.

9. The package structure of claim 8, wherein the metal layer is physically coupled to the seal ring structure.

10. A package structure, comprising:
a package substrate;
an interposer bonded to the package substrate by way of first-type bumps;
a first underfill surrounding the first-type bumps;
a first die and a second die bonded to the interposer by way of second-type bumps;
a second underfill surrounding the second-type bumps;
a metal layer interfacing the interposer, the second underfill, sidewalls of the first die, and sidewalls of the second die;
a first molding material over the metal layer;
a thermal interface material disposed over the first molding material, the metal layer, the first die, and the second die; and
a second molding material over the package substrate and surrounding the first underfill and the first molding material.

11. The package structure of claim 10, wherein the metal layer comprises titanium-copper, copper, or gold.

12. The package structure of claim 10, wherein the second molding material interfaces the metal layer and the first underfill.

13. The package structure of claim 10, wherein a top surface of the second molding material is free of the thermal interface material.

14. The package structure of claim 10, further comprising:
a metal ring attached to a top surface of the second molding material.

15. The package structure of claim 14, wherein the metal ring comprises aluminum (Al), copper (Cu), iron (Fe), nickel (Ni), cobalt (Co), or an alloy thereof.

16. A package structure, comprising:
a package substrate;
an interposer bonded to the package substrate by way of first-type bumps;
a first underfill surrounding the first-type bumps;
a first die and a second die bonded to the interposer by way of second-type bumps;
a second underfill surrounding the second-type bumps;
a metal layer interfacing the interposer, the second underfill, sidewalls of the first die, and sidewalls of the second die;
a first molding material over the metal layer;
a second molding material over the package substrate and surrounding the first underfill and the first molding material; and
a thermal interface material disposed over the first molding material, the second molding material, the metal layer, the first die, and the second die,
wherein the metal layer comprises titanium-copper, copper, or gold.

17. The package structure of claim 16, further comprising:
a metal ring attached to a top surface of the second molding material.

18. The package structure of claim 17, wherein the thermal interface material interfaces an inner sidewall of the metal ring.

19. The package structure of claim 17, wherein the thermal interface material comprises aluminum, titanium, nickel-vanadium (NiV), or gold.

20. The package structure of claim 16, wherein the second molding material interfaces the metal layer and the first underfill.
